(19) United States
(12) Patent Application Publication
(10) Pub. No.: US 2001/0012726 A1
(43) Pub. Date: Aug. 9, 2001

(54) STACKED MODULE CONNECTOR

(76) Inventors: SEAN P. O'NEAL, ROUND ROCK, TX (US); REYNOLD L. LIAO, AUSTIN, TX (US); DEEPAK SWAMY, AUSTIN, TX (US)

Correspondence Address: BAKER & BOTTS, ONE SHELL PLAZA, 910 LOUISIANA, HOUSTON, TX, 770024995

(21) Appl. No.: 09/417,821

(22) Filed: Oct. 14, 1999

(51) Int. Cl. H05K 1/00; H01R 12/00; H01R 13/60; H01R 13/66

(52) U.S. Cl. 439/540.1; 439/74

(57) ABSTRACT

A connector suitable for providing an electrical connection between a plurality of modules with card edge connections and the motherboard in a stacked configuration is disclosed. This connector includes a plurality of housings, each containing a socket with contacts suitable for providing an electrical contact between a module and the motherboard. These housings are stacked in a direction normal to the surface on which the connector is mounted, such as the motherboard. These housings can also be offset with respect to each other such that the modules are secured to the connector in a stacked and stepped configuration.

### TECHNICAL FIELD

The present invention relates in general to the field of electrical connectors and more specifically to an electrical connector for establishing a connection between a motherboard of a computer system and two or more electrical or electronic modules.

### BACKGROUND

The general trend in computer component and system design is towards miniaturization. As computers become increasingly common in both the workplace and household, computer designers will need to be more sensitive to the environment in which the computers will be used. Desktop and portable computers will need to become smaller in order to meet the growing expectation that consumer and business electronics be portable yet powerful. While smaller computers tend to be more portable, they naturally have less space available for electronic components. One aspect of this design conflict is the need to maximize the use of diminishing motherboard space. This particular problem is especially evident in designing laptop computers.

As the communications infrastructure of the computer, it is on the motherboard that memory slots and all other adapters and modules are installed. Today, portable computers are being designed with more memory slots as they continue to accommodate larger screens, such as liquid crystal displays, and modules. However, since portable computers should not be designed to be larger, motherboard space is still constrained. The need to move to component based central processing unit (CPU) designs, as opposed to modules, due to the emergence of next generation high speed bus architectures, has further accentuated mother board space constraints. Supporting chips which used to be placed on daughter cards are now being placed on the motherboard. Due to most of the complex CPU components being area array packages, the other side of the motherboard on which these components are placed is now lost for placing any active devices. However, due to the increasing memory requirements of current software, the need for more memory expansion capability continues.

Current computer systems, such as the LATITUDE and INSPIRON laptop computers manufactured by Dell Computer Corporation of Austin, Tex., are being designed to have as many as three memory slots on the motherboard. In designing computer systems, designers must locate space on the motherboard for these memory slots, while at the same time placing the memory slots in a location that does not impede the performance of the memory modules. For example, the trace length must be minimized in order to reduce losses in the electrical connection.

Additional difficulties in locating the memory slots on the motherboard arise because of the spacing requirements of the next generation memory technologies. One example of a next generation memory module is designed and manufactured by Rambus Inc. of Mountain View, Calif. It is a requirement of Rambus's SoRIMM (Small Outline Rambus In-Line Memory Module) that the pin to pin distance between the memory slots be less than 0.511. Due to the structure of the Rambus SoRIMM, the minimum space between two memory slots is limited by the width of the SoRIMM itself, which is approximately 1.25″. Overcoming these two requirements requires the staggering of the placement of the connectors, which further exacerbates the space limitation on the surface of the motherboard.

Desktop computers use connectors that hold the memory modules perpendicular to the motherboard or at a large angle. Portable computers, even those intended to serve as desktop replacements, are not tall enough to accommodate this arrangement. For example, while up to three RIMM modules may be used on a desktop computer's motherboard, portable computers have not added a third memory slot because of space constraints.

Trace length is another consideration for computer designers. One solution to the trace length problem is to place one of the modules on the other side of the motherboard from the other two modules. This solves the trace length problem, but does not solve the problem of board space. It is also more difficult for the consumer and the factory to physically access the memory since the memory modules are now located on both sides of the motherboard.

Therefore, a need exists for a means of allowing two or more modules to be placed on the motherboard in a manner which is space efficient and does not impede performance or physical access to the modules.

### SUMMARY

In accordance with teachings of the present disclosure, a system and method are described for a connector that allows two or more modules to be stacked parallel to each other. The modules could be offset slightly to allow better access to the modules closer to the motherboard and a visual reference of which module is installed in the slots. The connector could consist of two or more modules. For the case of three modules and the motherboard being offset from the plastics, it may be preferable to stack all three with one connector or use a stacked connector next to a standard single connector. The connector should still be Surface Mounted Technology (SMT) with longer tabs for the more distant modules. Note that many portable computers (particularly desktop replacements) are being designed with internal modules, such as compact disc/floppy disk drives, that typically are placed under the motherboard. This will push the motherboard away from the base plastics by at least the thickness of the compact disc/floppy disk drive. This distance is generally at least 12.7 mm and is not currently being exploited. For example, a SoDIMM or SoRIMM memory module is about 4 mm, leaving unused space below the memory module. The stacked module connector utilizes this otherwise wasted space to effectively increase the available system memory.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is a perspective view of the connector and terminals of the present invention.

FIG. 2 is a perspective view of the connector and terminals of the present invention with a spacer.

FIG. 3 is a perspective view of the connector and terminals of the present invention, wherein the connector employs latches to secure the modules.

FIG. 4 is a perspective view of the connector and terminals of the present invention wherein the connector employs latches and a spacer.

FIG. 5 is a front view of the connector and terminals of the present invention wherein the top housing is wider than the bottom housing.

### DETAILED DESCRIPTION

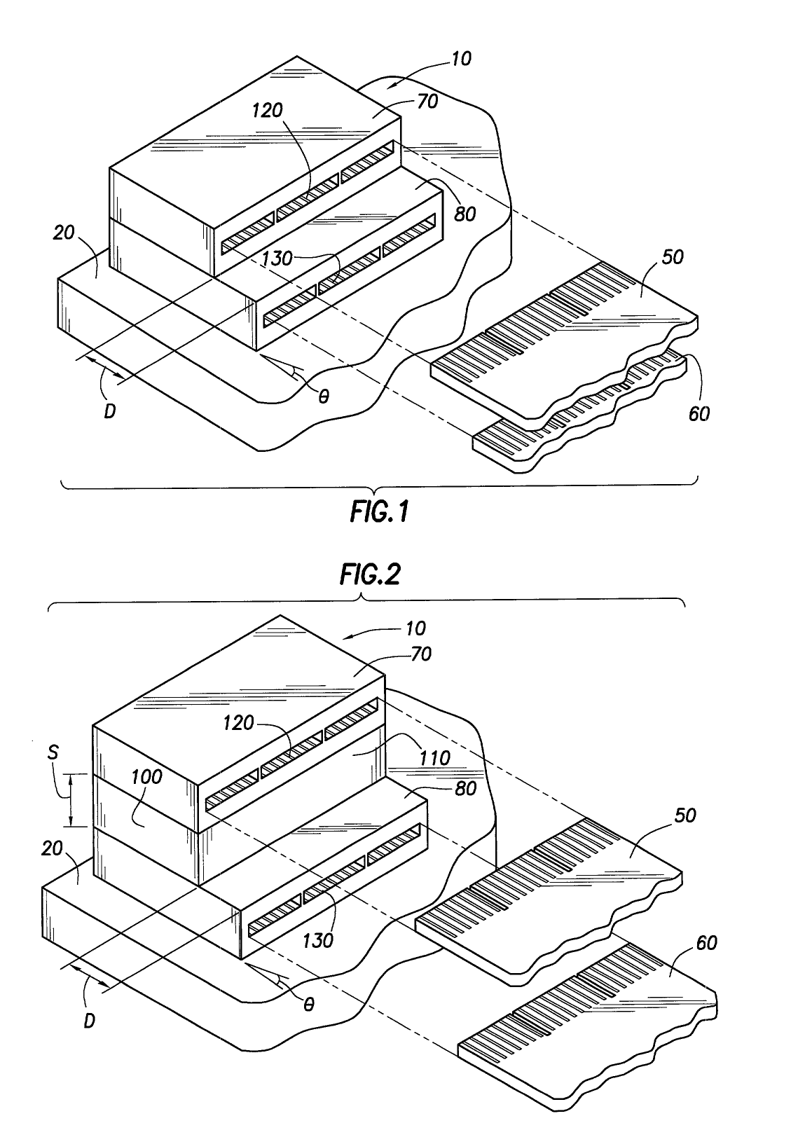

Preferred embodiments and their advantages are best understood by reference to FIGS. 1 through 5, wherein like numbers are used to indicate like and corresponding parts.

Shown in FIG. 1 is connector 10 for providing a electrical connection between two modules, 50 and 60, to a motherboard 20 on which the connector 10 is mounted. This connector 10 comprises housings 70 and 80 which are disposed in a direction normal to the motherboard 20. In other words, housings 70 and 80 are configured in a stacked position on the motherboard 20. Housings 70 and 80 contain slots 120 and 130 respectively. However, the present invention need not be limited to two housings. Slots 120 and 130 are intended to provide an electrical connection for modules 50 and 60, respectively, to the motherboard 20 Housings 70 and 80 are preferably offset with respect to each other by selected distance D. This offset gives the module connector a stacked and stepped configuration. Where the offset distance D is zero, larger modules located in the top slots will obscure smaller modules located in the bottom slots. In addition, housings 70 and 80 may be aligned at an acute angle θ with respect to the motherboard 20. This acute angle may be zero degrees. Preferably, this acute angle is zero, resulting in modules 50 and 60 being parallel to the motherboard 20.

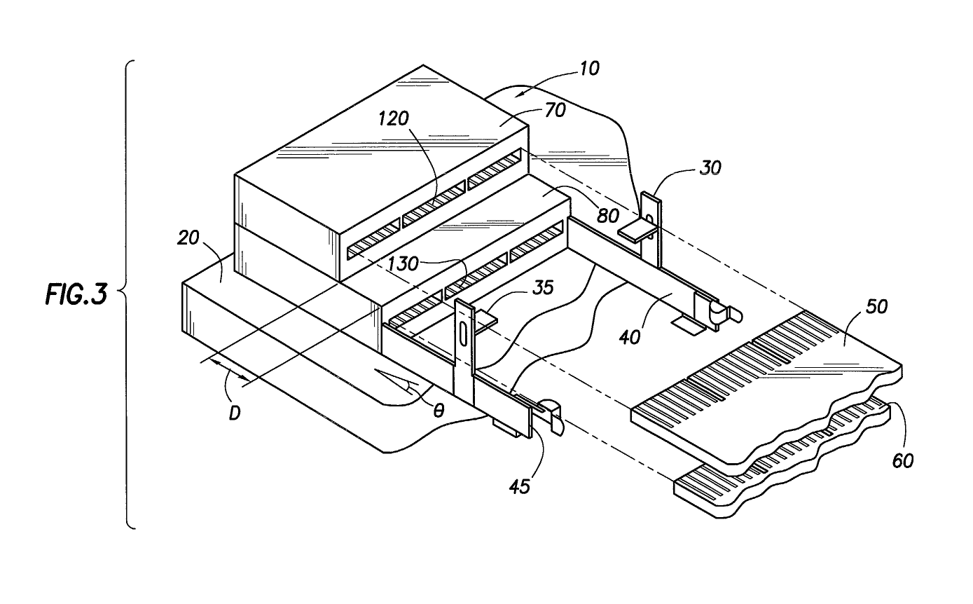

FIG. 2 discloses a spacer 100 between housing 70 and 80 of variable width S to provide a space between modules 50 and 60. In another embodiment of the invention, thermally insulating or conducting material can be mounted on the face 110 of spacer 100. Alternatively, spacer 100 may be made from such thermally insulating or conducting material. Alternatively, or in addition, a vibration damper made of shock absorbent material may be mounted on face 110 to prevent modules 50 and 60 from being forcibly contacted against each other. Alternatively, spacer 100 may be made from such shock absorbant material.

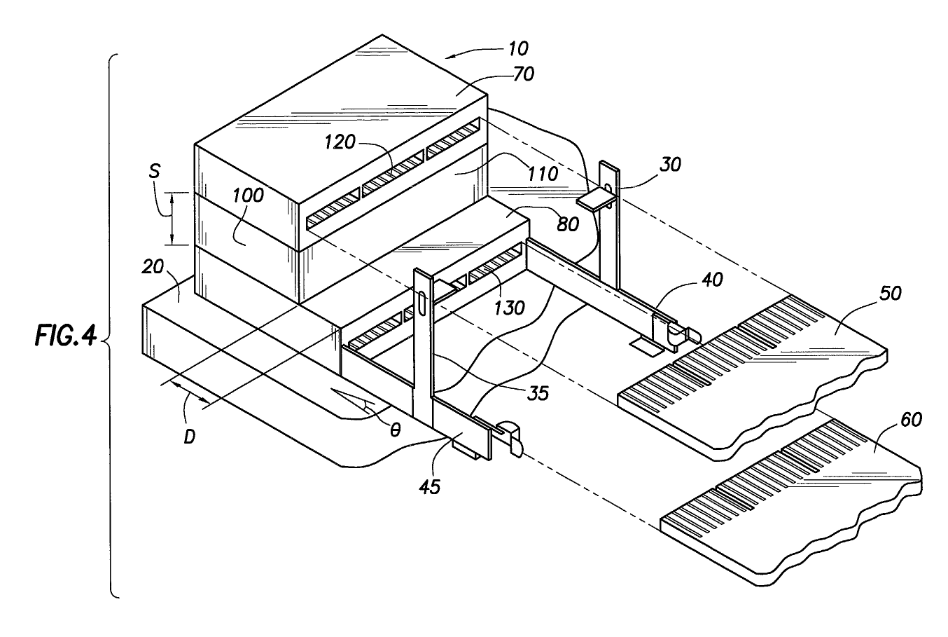

FIG. 3 discloses an alternative embodiment of the present invention wherein the connector employs a latch to secure the modules. Module 50 is secured to socket 120 by latches 35 and 30. Module 60 is secured to socket 130 by latches 45 and 40. The present invention does not require latches or that the latches be a part of the connector 10. For example, the latch may be attached to the motherboard itself, rather than the connector. FIG. 4 discloses another embodiment of the invention, wherein the connector employs latches and a spacer.

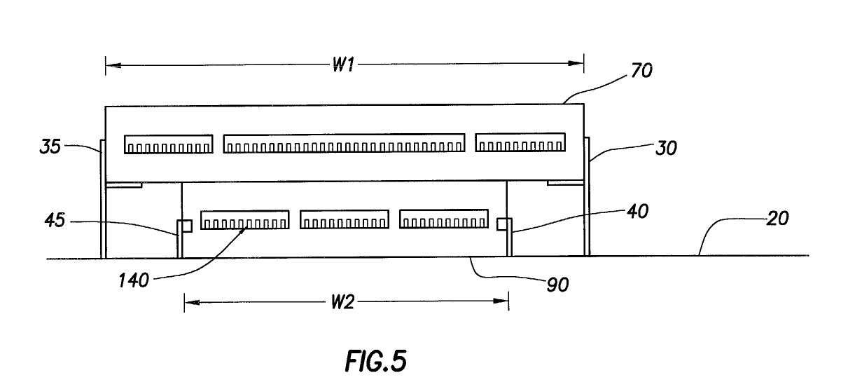

FIG. 5 illustrates that the width W1 of housing 70 need not be equal to the width W2 of housing 90 since the invention is not limited to connectors for providing electrical connections between the motherboard and modules of the same type or size. Where housing 70 has a width W1 which is greater than the width W2 for housing 90, a module (not shown) can be placed in slot 140 with greater ease since latches 30 and 35 are not obstructing physical access to slot 140.

The present invention need not be limited to SoDIMM or SoRIMM memory modules. For example, other modules with card edge connections, such as those utilizing the mini-PCI type III standard, may be stacked. Other types of modules suitable for use with the present invention include video, video capture, audio, modem, network, 802.11, MPEG decoders and wireless communication devices such as BLUETOOTH. Since the modules need not be the same size, the module connector can be used to stack different types of modules. For example, a SoRIMM memory module may be placed in one socket, while a mini-PCI type module may be placed in another socket.

There are several major benefits to this arrangement. One advantage is that the 3-D space utilization in a notebook is maximized. Another advantage is that the memory trace lengths, particularly on a serial bus like Rambus are greatly decreased. As a result, performance is not adversely affected. Another benefit is that the memory door to access the memory modules can be much smaller, allowing the computer's plastics to have smaller access panels and maintain more structural integrity.

Furthermore, by providing for an offset in the manner in which the modules are stacked, the present invention possesses several additional advantages over existing connectors. One advantage is that the offset provides greater physical access to the modules for the purposes of inserting or removing the modules from the connector. In the case of a connector where the modules are completely overlapping, it would be more difficult to insert or remove modules which are located closer to the motherboard. Another benefit is that the offset allows for improved visual confirmation of the location and presence of modules located closer to the motherboard. If the modules are completely overlapping, some modules may be obscured. The offset also provides for better thermal properties by allowing for heat dissipation. Heat may become trapped between modules where the connector provides for a stacked and completely overlapping configuration. The offset also serves to minimize the trace length problem. In the case where there is no offset, the modules are located directly on top of one another and, as a result, the contacts for the top module must bend around the lower modules in order to connect with the motherboard. Where there is an offset, the contacts can have a direct path to the motherboard which minimizes the required pin length.

Although the disclosed embodiments have been described in detail, it should be understood that various changes, substitutions and alterations can be made to the embodiments without departing from their spirit and scope.

What is claimed is:

1. A module connector comprising:
an interface for securing the module connector to a socket of a motherboard; and
a plurality of housings, each containing a slot, wherein the slots include electrical contacts, and are each adapted to receive a module and provide a connection from the module to the motherboard.

2. The module connector of claim 1, wherein the housings are disposed in a direction normal to the motherboard.

3. The module connector of claim 1, wherein the slots provide a connection for the modules to the motherboard at an acute angle.

4. The module connector of claim 3, wherein the acute angle is approximately zero.

5. The module connector of claim 1, wherein the housings are offset at a selected distance with respect to each other.

6. The module connector of claim 1, further comprising one or more latches for securing a plurality of modules to the module connector.

7. The module connector of claim 1, wherein a upper housing has a greater width than a lower housing.

8. A module connector comprising:
an interface for securing the module connector to a socket of a motherboard;
a latching mechanism for securing the connection of a plurality of modules to the module connector;
a plurality of housings, wherein the housings are disposed in a direction normal to the motherboard, and are offset at a selected distance with respect to each other; and
a plurality of slots, each located in a housing, wherein the slots include electrical contacts, and provide a connection for the modules to the motherboard at a selected acute angle.

9. The module connector of claim 8, wherein the selected acute angle is zero.

10. The module connector of claim 8, wherein the housings are vertically spaced from each other, and one or more heat sinks are placed between the slots.

11. The module connector of claim 8, wherein the housings are vertically spaced from each other, and one or more vibration dampers are placed between the slots.

12. The module connector of claim 8, wherein the module connector comprises a base portion and a top portion, wherein the top portion has a greater width in a direction parallel to the motherboard than the base portion.

13. The module connector of claim 8, further comprising one or more latches for securing a plurality of modules to the module connector.

14. A computer system comprising:
a motherboard; and
a module connector, wherein the module connector comprises:
an interface for securing the module connector to a socket of the motherboard; and
a plurality of slots, wherein the slots include electrical contacts, and are each sized to receive a module and provide a connection from the module to the motherboard.

15. The computer system of claim 14, wherein each slot of the module connector is contained in a housing and the housings are disposed in a direction normal to the motherboard.

16. The computer system of claim 14, wherein the slots of the module connector provide a connection for the modules to the motherboard at an acute angle.

17. The computer system of claim 16, wherein the acute angle is zero.

18. The computer system of claim 14, wherein each slot of the module connector is contained in a housing and the housings are offset with respect to each other.

19. The computer system of claim 14, wherein the module connector further comprises one or more latches for securing a plurality of modules to the module connector.

20. The computer system of claim 14, wherein the module connector comprises a base portion and a top portion, wherein the top portion has a greater width in a direction parallel to the motherboard than the base portion.

21. A computer system comprising:
a motherboard; and
a module connector comprising:
an interface for securing the module connector to a socket of the motherboard; and
a plurality of slots, wherein the slots include electrical contacts, and are disposed in a direction normal to the motherboard, and provide a connection for the modules to the motherboard at a selected acute angle, and are offset at a selected distance with respect to each other.

22. The computer system of claim 21, wherein the selected acute angle is zero.

23. The computer system of claim 21, wherein each slot of the module connector is contained in a housing and the housings are vertically spaced from each other, and one or more heat sinks are placed between the housings.

24. The computer system of claim 21, wherein each slot of the module connector is contained in a housing and the housings are vertically spaced from each other, and one or more vibration dampers are placed between the housings.

25. The computer system of claim 21, wherein the module connector further comprises a base portion and a top portion, wherein the top portion has a greater width in a direction parallel to the motherboard than the base portion.

26. The computer system of claim 21, wherein the module connector further comprises one or more latches for securing a plurality of modules to the module connector.
